(19) United States
(12) Patent Application Publication
(10) Pub. No.: US 2009/0239315 A1
(43) Pub. Date: Sep. 24, 2009

(54) METHOD AND SYSTEM FOR PROCESSING TEST WAFER IN PHOTOLITHOGRAPHY PROCESS

(75) Inventor: Yung-Yao Lee, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ProMOS TECHNOLOGIES INC., Hsinchu (TW)

(21) Appl. No.: 12/111,973

(22) Filed: Apr. 30, 2008

(30) Foreign Application Priority Data
Mar. 24, 2008 (TW) 97110423

(51) Int. Cl. H01L 21/66; G06F 17/50; G01R 31/00

(52) U.S. Cl. 438/16; 716/5; 702/117; 257/E21.53

(57) ABSTRACT

A method and a system for processing a test wafer in a photolithography process are provided for processing an i^{th} layer of the test wafer, and i is a positive integer. In the present method, a compensation value is calculated according to historical compensation behaviors of an equipment, relationships between the i^{th} layer and other layers, and offsets generated in performing a non-photolithography process on the test wafer. Then, the test wafer is processed according to the compensation value. A determination on whether the test wafer meets a design specification is then made. Rework is performed on the test wafer if the test wafer does not meet the design specification. Accordingly, an adjustable compensation value is used to process the test wafer and avoid unnecessary rework. The possibility of rework on the test wafer is reduced so as to increase the efficiency of the photolithography process.

### CROSS-REFERENCE TO RELATED APPLICATION

This application claims the priority benefit of Taiwan application serial no. 97110423, filed on Mar. 24, 2008. The entirety of the above-mentioned patent application is hereby incorporated by reference herein and made a part of specification.

### BACKGROUND OF THE INVENTION

1. Field of the Invention

The present invention relates to a method and a system for processing a test wafer, and particularly relates to a method and a system for processing a test wafer in a photolithography process.

2. Description of Related Art

For semiconductor manufacturers, complexity of a photolithography process mainly relates to a quantity of products, a number of product levels, and a number of equipments in a photolithography area. The emphasis of the photolithography process lies in two factors, overlay (OL) and critical dimension (CD). One of the keys to the quality of wafer conductivity and the process yield is whether the levels are properly aligned and whether the critical dimension is controlled within design specification.

FIG. 1 is a flow chart of a conventional process on a lot. Generally, when a lot arrivals at an equipment, one wafer in the lot is selected as a test wafer to ensure that the entire lot will meet the specification after the process. Then, as shown in step 110, an exposure process is performed on the test wafer according to a predetermined base value. An overlay and a critical dimension are measured by a measurement equipment so as to obtain a measurement result to compensate a process on the mother lot. In a conventional practice, a process on the test wafer is mostly performed at a predetermined base value set to zero. As a result, the test wafer after the process would not meet the design specification in most cases. Therefore, the test wafer has to be reworked in step 120. Then, as shown in step 130, the test wafer is merged into the mother lot. Finally, in step 140, all wafers in the mother lot are processed according to the obtained measurement result to ensure that the lot will meet the design specification after the process.

However, the rework on the test wafer is extremely time-consuming. The process on the mother lot must be delayed until the rework on the test wafer is finished as illustrated in FIG. 1. Such delay results in low efficiency of the lot process and reduces the throughput. Furthermore, the conventional process on the test wafer is according to a fixed predetermined base value with no adjustment made depending on the product type or equipment condition. The rework on the test wafer is almost always necessary, which not only affects lot process time but also wastes photoresist and chemical materials and further increases manufacturing costs.

### SUMMARY OF THE INVENTION

In light of the above, the present invention provides a method for processing a test wafer in a photolithography process. An adjustable compensation value is used in a process of the test wafer to reduce a possibility of reworking the test wafer.

The present invention provides a system for processing a test wafer in a photolithography process according to an adjustable compensation value and for directly processing a mother lot corresponding to the test wafer based on the compensation value and a measurement result to increase efficiency of the process on the mother lot.

The present invention provides a method for processing a test wafer in a photolithography process, which processes an i^{th} level of the test wafer using an equipment, wherein i is a positive integer. The method calculates a compensation value based on historical compensation behaviours of the equipment, relationships between the i^{th} level and other levels, and a offset generated on the test wafer after a non-photolithography process. The aforementioned other levels are different from the i^{th} level. Then, the process on the test wafer is performed according to the compensation value and a determination on whether the test wafer meets a design specification is made. If the test wafer fails to meet the design specification, rework on the test wafer is performed.

In another aspect, the present invention provides a system for processing a test wafer in a photolithography process. The system includes an equipment, a compensation value generating module, and a control module. The equipment is used to process an i^{th} level of the test wafer, wherein i is a positive integer. The compensation value generating module is coupled to the equipment and calculates a compensation value based on historical compensation behaviours of the equipment, relationships between the i^{th} level and other levels, and a offset generated on the test wafer after a non-photolithography process, wherein the aforementioned other levels are different from the i^{th} level. The control module is connected to the equipment and the compensation value generating module to control the equipment for processing the test wafer according to the compensation value, to determine whether the test wafer meets a design specification, and to make the test wafer being reworked in the case when the test wafer does not meet the design specification.

The present invention performs a process on the test wafer based on an adjustable compensation value with learning capability so as to significantly reduce the possibility of rework on the test wafer as well as the waste of chemical materials in the photolithography process and to increase the efficiency of the photolithography process.

In order to make the aforementioned and other objects, features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart of a conventional process on a lot.

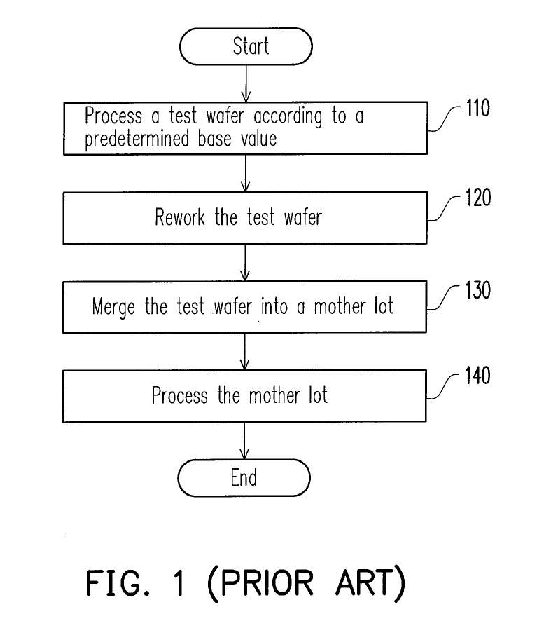

FIG. 2 is a block diagram of a system for processing a test wafer in a photolithography process according to an embodiment of the present invention.

FIG. 3 is a flow chart of a method for processing a test wafer in a photolithography process according to an embodiment of the present invention.

FIG. 4 is a flow chart illustrating how to determine whether a test wafer meets a design specification according to an embodiment of the present invention.

### DESCRIPTION OF EMBODIMENTS

During a process of a lot, when the lot arrivals at an equipment, a wafer is selected as a test wafer from the lot (referred to as the mother lot). Then, an adjustment is made on the equipment according to a measurement result from a process of the test wafer. Finally, processes on other wafers of the mother lot are performed to ensure that the mother lot meets a design specification. However, in the above process, the possibility of rework on the test wafer is quite high. Under the condition that each rework consumes a great deal of waiting time, a design of a mechanism that reduces the possibility of rework on the test wafer would certainly promote the efficiency of the photolithography process. Based on the above points, the present invention develops a method and a system for processing a test wafer in a photolithography process. In order to make the present invention more comprehensible, embodiments are described below as the examples to prove that the invention can actually be realized.

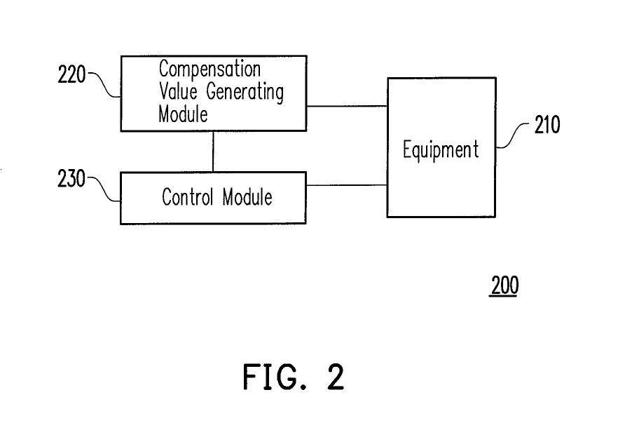

FIG. 2 is a block diagram of a system for processing a test wafer in a photolithography process according to an embodiment of the present invention. Referring to FIG. 2, a test wafer processing system 200 generates various compensation values according to factors such as conditions of a test wafer and an equipment to reduce a possibility of rework on the test wafer during processing a lot. The test wafer processing system 200 comprises an equipment 210, a compensation value generating module 220, and a control module 230.

In the present embodiment, the test wafer comprises a plurality of levels. The equipment 210 may, for example, process an i^{th} level, wherein i is a positive integer. The compensation value generating module 220 connected to the equipment 210 calculates the compensation value required in the process of the test wafer. In the present embodiment, the compensation value generating module 220 calculates the compensation value based on factors such as historical compensation behaviours of the equipment 210, relationships between the i^{th} level and other levels, and a offset generated on the test wafer after a non-photolithography process. In another embodiment, in addition to the above mentioned factors, the compensation value generating module 220 may also calculate the compensation value according to a time of a previous process on the lot by the equipment 210, experience values of the equipment 210, process results of levels similar to the i^{th} level, and process results of an equipment similar to the equipment 210.

The control module 230 is respectively connected to the equipment 210 and the compensation value generating module 220 to control the equipment 210 to process the test wafer according to the compensation value calculated by the compensation value generating module 220. In addition, the control module 230 has a mechanism to determine whether the test wafer meets a design specification, and makes the test wafer being reworked if the test wafer does not meet the design specification.

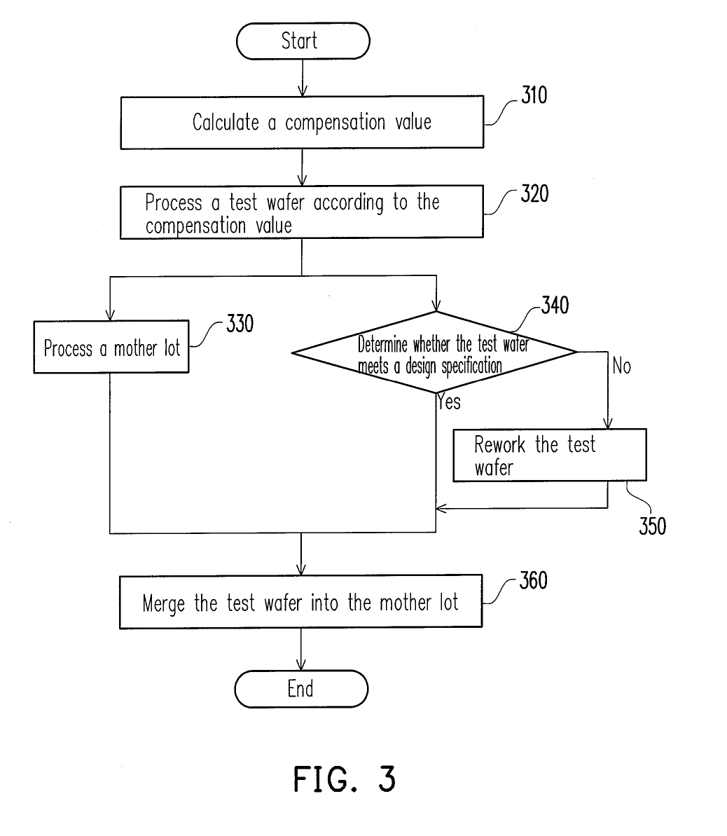

To further illustrate the detailed steps about how the compensation value generating module 220 calculates the compensation value and how the control module 230 determines whether the test wafer requires rework, another embodiment is provided below to more completely explain the operation steps of the test wafer processing system 200 of the present invention. FIG. 3 is a flow chart of a method for processing a test wafer in a photolithography process according to an embodiment of the present invention. Please refer to FIG. 2 and FIG. 3 at the same time. First, as shown in step 310, the compensation value generating module 220 calculates the compensation value corresponding to the test wafer before processing the test wafer.

In the present embodiment, the compensation value generating module 220, for example, calculates the compensation value based on the historical compensation behaviours of the equipment 210, wherein the historical compensation behaviours refer to m first type compensation behaviours corresponding to previous m times that the equipment 210 processed the i^{th} level (m is a positive integer). For the purpose of illustration, suppose that m equals to 3 and the equipment 210 has processed the i^{th} level of the test wafer for 100 times in the past three months. That is, 100 entries of information on the first type compensation behaviours may be provided. Accordingly, the compensation value generating module 220 calculates the compensation value based on the 98^{th}, 99^{th} and 100^{th} first type compensation behaviours before the 101^{st} process on the i^{th} level.

More specifically, each wafer design sets a different measurement target for overlay and critical dimension errors. Thus, the compensation value generating module 220 first calculates a weighted value corresponding to the m first type compensation behaviours based on the measurement target and the measurement results from the m processes on the i^{th} level by the equipment 210. Then, the compensation value generating module 220 calculates the compensation value according to the m first type compensation behaviours and the weighted value corresponding thereto. For example, the compensation value is calculated based on a weighted average of the m first type compensation behaviours in the present embodiment. For the purpose of illustration, C_{H}_{_{—}}_{FB} represents the above weighted average and C_{H}_{_{—}}_{FB} may be calculated with following equation:

$${c}_{H\_FB} = {\sum }_{x = 1}^{m} {w}_{x} [ {PPM}_{x - 1} - g \cdot B \cdot ( {PPM}_{x - 1} - {PPM}_{target} ) ] / Z , \\ {\sum }_{x = 1}^{m} {w}_{x} = Z .$$

PPMₓ₋₁ represents the first type compensation behaviour corresponding to the (x−1)^{th} process on the i^{th} level by the equipment 210. PPM_{target} represents the predetermined measurement target. g and B are a damping coefficient and a slope compensation value, respectively. wₓ is the weighted value corresponding to the x^{th} first type compensation behaviour.

The following detailed steps illustrate how the compensation value generating module 220 calculates the weighted value corresponding to each first type compensation behaviour. First, the compensation value generating module 220 calculates the differences between the m measurement results and the measurement target, and then calculates a weighted value based on the order of the above differences and a predetermined sum of the weighted values.

For example, before the 101^{st} process on the i^{th} level, suppose the compensation value generating module 220 calculates the compensation value according to the three first type compensation behaviours corresponding to the previous three times (i.e. the 100^{th}, the 99^{th}, and the 98^{th} time) that the equipment 210 processed the i^{th} level. The differences between the measurement results and the measurement target generated during the previous three times that the equipment 210 processed the i^{th} level are U₁₀₀, U₉₉, U₉₈, respectively. When |U₁₀₀|≦|U₉₉|≧|U₉₈|, it means that with the increase in the number of processes, the degree of offset increases as well. Thus, a larger weighted value should be assigned to a first type compensation behaviour of a large offset to correct the error. If the predetermined sum of the weighted values is 10 and the weighted values corresponding to the three first type compensation behaviours can not repeat, then in the present embodiment, the weighted values corresponding to the 100^{th}, the 99^{th}, and the 98^{th} first type compensation behaviours are 7, 2, and 1, respectively. In other words, as long as the predetermined sum of the weighted values is given, the compensation value generating module 220 will automatically calculate the weighted values by way of permutation based on the differences between the measurement results and the measurement target.

In another embodiment, if the m previous processes on the i^{th} level by the equipment 210 were performed a while ago such that the dependability of the compensation values is diminished, the compensation value generating module 220 will calculate the compensation values based on historical compensation behaviours of processes on other levels by the equipment 210. In detail, the historical compensation behaviours refer to a plurality of second type compensation behaviours corresponding to processes on a j^{th} level by the equipment 210, wherein j is a positive integer. The j^{th} level is the most recent level that the equipment 210 processed on and belongs to other products, for example. Thus, the j^{th} level differs from the i^{th} level. In the present embodiment, the compensation value generating module 220 calculates the compensation values by obtaining the first type compensation behaviour corresponding to the process on the i^{th} level by the equipment 210 at a certain time, the second type compensation behaviour corresponding to the process on the j^{th} level by the equipment 210 at the certain time, and the second type compensation behaviour corresponding to the most recent process on the j^{th} level by the equipment 210. The compensation value is calculated with the following equation in the present embodiment:

c_{machine}_{_{—}}_{offset}=∇n_{—}j_layer −∇n−k_{—}j_layer+∇n−k_{—}i_layer

C_{machine}_{_{—}}_{offset} represents the offset of the equipment 210. ∇n_j_layer represents process data generated during the process on the j^{th} level by the equipment 210 at time n (e.g. the date of the process). ∇n−k_j_layer and ∇n−k_i_layer respectively represent data generated during the processes on the j^{th} level and the i^{th} level by the equipment 210 at time n−k (i.e. the certain time, for example, a month ago). As such, the offset of the equipment 210 may be reflected in the calculation of the compensation value.

In another embodiment, because overlay precision among levels is very important for a photolithography process, if structure of a previous level tilts, a lower level must also shift. Accordingly, the compensation value generating module 220 calculates the compensation value based on a sum of the offsets between the i^{th} level and other levels. In the present embodiment, the other levels refer to all the levels above the i^{th} level (i.e. the 1^{st} level to the (i−1)^{th} level). The sum of offsets is C_{V}_{_{—}}_{FB}, for example:

$${c}_{V\_FB} = {\sum }_{y = 1}^{i - 1} {A}_{y} \cdot {α}_{y} \cdot {ϖ}_{y} .$$

In the above equation, α_{y} represents the offset of the y^{th} level and ω̅_{y} represents the weighted value corresponding to the y^{th} level. A_{y} is a calculation coefficient. When A_{y} is smaller than an offset limit, A_{y} is 0. When A_{y} is larger than or equal to the offset limit, A_{y} is 1.

In another embodiment, due to the fact that semiconductor fabrication may be divided into four fabrication modules, a structure of the test wafer may be affected in a non-photolithography area. In other words, even if the process results of the test wafer meet the requirements of the design specification for overlay and critical dimension, a structure tilt of the test wafer may still occur in the non-photolithography area. Therefore, in the present embodiment, the compensation value generating module 220, for example, obtains offsets generated from processes performed on the test wafer in a plurality of non-photolithography chambers and calculates the compensation value based the weighted average of the above offsets. C_{chamber}_{_{—}}_{offset} is, for example,

$${C}_{chamber\_offset} = {\sum }_{z = 1}^{m} {w}_{z} \{ {[ {PPM}_{z - 1} - {PPM}_{target} ]}_{ADI} - {[ {PPM}_{z - 1} - {PPM}_{targer} ]}_{AEI} \} / Z , \\ {\sum }_{x = 1}^{m} {w}_{x} = Z .$$

PPM_{z-1} represents the first type compensation behaviour corresponding to a (z−1)^{th} process on the i^{th} level by the equipment 210, PPM_{target} represents the predefined measurement target relatives to the design, and w_{z} is the weighted value. In the above equation, ADI represents the results after development inspection and AEI represents the results after etch inspection.

Continuing from the above embodiment, in another embodiment of the present invention, the compensation value generating module 220 calculates C_{H}_{_{—}}_{FB} with reference to the m processes on the i^{th} level by the equipment 210 before the test wafer processing system 200 starts to process the i^{th} level of the test wafer. Then, the compensation value generating module 220 calculates C_{machine}_{_{—}}_{offset}, C_{V}_{_{—}}_{FB} and C_{chamber}_{_{—}}_{offset} and uses the sum of C_{H}_{_{—}}_{FB}, C_{machine}_{_{—}}_{offset}, C_{V}_{_{—}}_{FB}, and C_{chamber}_{_{—}}_{offset} as the compensation value for processing the test wafer to reflect the conditions of the equipment 210 and the test wafer during the process and to reduce the possibility of rework on the test wafer.

Please revert back to FIG. 3. After the compensation value generating module 220 calculates the compensation value, the control module 230 controls the equipment 210 to process the test wafer according to the compensation value, as shown in step 320. In the present embodiment, the equipment 210, for example, performs an exposure process on the test wafer and the control module 230 obtains the corresponding measurement results after the exposure process. Meanwhile, as shown in step 330, the control module 230 instructs the equipment 210 to process the other wafers in the lot (i.e. the mother lot) corresponding to the test wafer according to the compensation value and the measurement results.

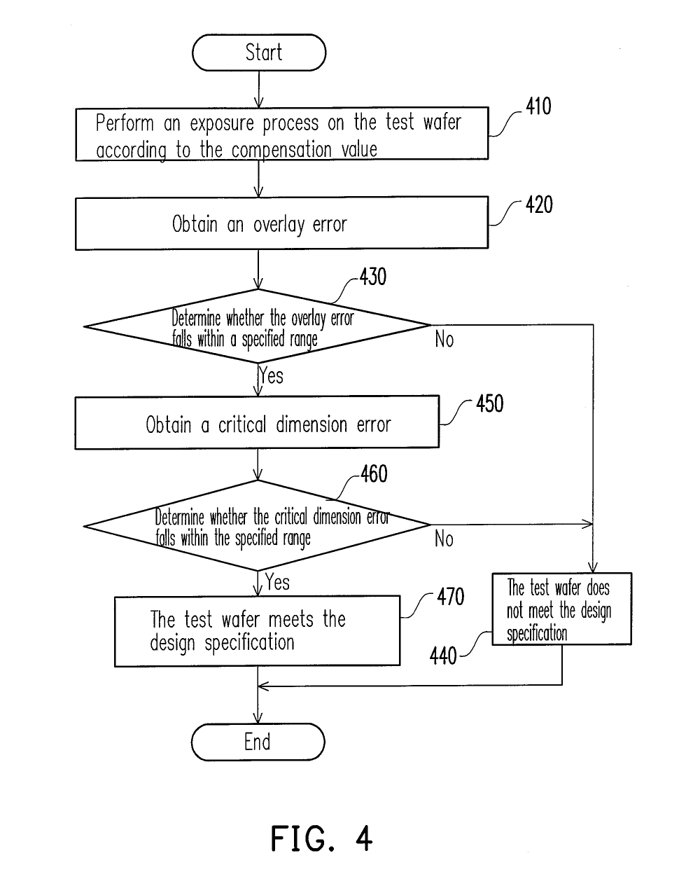

In addition, in step 340, the control module 230 determines whether the test wafer meets the design specification after the process. FIG. 4 is a flow chart illustrating how to determine whether a test wafer meets the design specification according to an embodiment of the present invention. Refer to FIG. 4. First, the control module 230 instructs the equipment 210 to perform an exposure process according to the compensation value (step 410). Then, the control module 230 obtains an overlay error measured by an overlay measurement equipment (step 420), and determines if the overlay error falls within a specified range relative to the design (step 430). If the overlay error is outside the specified range, this means the test wafer does not meet the design specification after the process (step 440). However, if the overlay error falls within the specified range, the control module 230 then obtains a critical dimension error measured by a critical dimension measurement equipment (step 450) and determines if the critical dimension error falls within the specified range (step 460). If the critical dimension error is outside the specified range, this means the test wafer does not meet the design specification (step 440). However, if the critical dimension error falls within the specified range, this means the test wafer meets the design specification after the process (step 470). It should be noted that the overlay error and the critical dimension error correspond to different specified ranges, respectively, which are predetermined according to the design.

In step 340 in FIG. 3, if the control module 230 determines that the test wafer meets the design specification, the processed test wafer is merged into the mother lot, as shown in step 360. On the contrary, if the control module 230 determines that the test wafer does not meet the design specification, rework must be performed on the test wafer, as shown in step 350. The test wafer after rework is merged into the mother lot in step 360. Accordingly, the entire process on the test wafer is completed.

It should be noted that the compensation value calculated by the compensation value generating module 220 can be used not only for processing the test wafer, but also for feedback processing of a lot. Alternatively speaking, a suitable compensation value is calculated by the compensation value generating module 220 before processing a lot, and then processes on all the wafers in the lot are performed to promote the yield of the process on the lot.

In summary, the method and the system for processing a test wafer in a photolithography process of the present invention include at least the following advantages:
1. A mechanism for calculating a compensation value that is adjustable and has learning capability is provided. The compensation value is calculated according to conditions of the equipment and the processed levels as well as historical compensation behaviour to further reduce the possibility of rework on the test wafer.
2. The possibility of rework on the test wafer is reduced to decrease the waste of photoresist and chemical materials and thereby saving costs.
3. After processing the test wafer using the compensation value, processes on the other wafers in the mother lot are directly performed based on the corresponding measurement results and the compensation value. Thus, when the test wafer does not meet the design specification after the process, the processes on the mother lot will not be delayed until the rework on the test wafer is completed. Thus, the entire process time is shortened to increase the efficiency of the photolithography process.
4. A determination mechanism is provided for judging the necessity of rework on the test wafer after the process on the test wafer according to the compensation value so as to avoid unnecessary rework and to save cost as well as promote efficiency.

It will be apparent to those of ordinary skills in the technical field that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for processing a test wafer in a photolithography process, wherein an i^{th} level of the test wafer is processed by an equipment, i being a positive integer, the method comprising:
calculating a compensation value based on at least one historical compensation behaviour of the equipment, a relationship between the i^{th} level and at least one of other levels, and an offset generated by a non-photolithography process on the test wafer, wherein the other levels are different from the i^{th} level;
processing the test wafer according to the compensation value and determining whether the test wafer meets a design specification; and
reworking the test wafer if the test wafer fails to meet the design specification.

2. The method for processing the test wafer in the photolithography process according to claim 1, wherein the historical compensation behaviours comprise m first type compensation behaviours corresponding to previous m processes on the i^{th} level by the equipment, and m is a positive integer.

3. The method for processing the test wafer in the photolithography process according to claim 2, wherein the step of calculating the compensation value based on the historical compensation behaviours comprises:
generating a weighted value corresponding to each of the first type compensation behaviours based on a measurement target and m measurement results generated in the previous m processes on the i^{th} level by the equipment; and
calculating the compensation value based on the weighted values and the first type compensation behaviours.

4. The method for processing the test wafer in the photolithography process according to claim 3, wherein the step of generating the weighted values comprise:
respectively calculating a difference between each of the measurement results and the measurement target; and
generating the weighted values based on an order of the differences and a predetermined sum of the weighted values.

5. The method for processing the test wafer in the photolithography process according to claim 1, wherein the step of calculating the compensation value based on the relationship between the i^{th} level and the other levels comprises:
calculating the compensation value based on a sum of the offsets between the i^{th} level and the other levels, wherein the other levels are all the levels above the i^{th} level in the test wafer.

6. The method for processing the test wafer in the photolithography process according to claim 1, wherein the step of calculating the compensation value based on the offset generated by a non-photolithography process on the test wafer comprise:
obtaining the offset corresponding to a process on the test wafer by at least one non-photolithography chamber; and
calculating the compensation value based on a weighted sum of the offsets.

7. The method for processing the test wafer in the photolithography process according to claim 1, wherein the historical compensation behaviours comprise a plurality of second type compensation behaviours corresponding to processes on a j^{th} level by the equipment, the j^{th} level is different from the i^{th} level and is the level most recently processed by the equipment, and j is a positive integer.

8. The method for processing the test wafer in the photolithography process according to claim 7, wherein the step of calculating the compensation value based on the historical compensation behaviours comprises:
calculating the compensation value based on a first type compensation behaviour corresponding to the process on the i^{th} level by the equipment at a certain time, the second type compensation behaviour corresponding to the process on the j^{th} level by the equipment at the certain time, and the second type compensation behaviour corresponding to the most recent process on the j^{th} level by the equipment.

9. The method for processing the test wafer in the photolithography process according to claim 1, wherein after the step of processing the test wafer based on the compensation value comprises:
obtaining a measurement result generated from an exposure process performed on the test wafer based on the compensation value; and
processing a lot corresponding to the test wafer according to the compensation value and the measurement result.

10. The method for processing the test wafer in the photolithography process according to claim 1, wherein the step of processing the test wafer according to the compensation value and determining whether the test wafer meets the design specification comprises:
obtaining a measurement result generated from an exposure process performed on the test wafer based on the compensation value; and
determining that the test wafer meets the design specification if the measurement result falls within a specified range.

11. The method for processing the test wafer in the photolithography process according to claim 10, wherein the measurement result comprises an overlay error obtained from an overlay measurement equipment.

12. The method for processing the test wafer in the photolithography process according to claim 10, wherein the measurement result comprises a critical dimension error obtained from a critical dimension measurement equipment.

13. The method for processing the test wafer in the photolithography process according to claim 1, further comprising:
calculating the compensation value according to a time of a previous process on a lot by the equipment, an equipment experience value of the equipment, results of processes on levels similar to the i^{th} level, and results of processes by an equipment similar to the equipment.

14. A system for processing a test wafer in a photolithography process, comprising:
an equipment used to process an i^{th} level of a test wafer, wherein i is a positive integer;
a compensation value generating module coupled to the equipment to calculate a compensation value based on at least one historical compensation behaviour of the equipment, a relationship between the i^{th} level and at least one of other levels, and a offset generated by a non-photolithography process on the test wafer, wherein the other levels are different from the i^{th} level; and
a control module coupled to the equipment and the compensation value generating module to control the equipment to process the test wafer based on the compensation value, to determine whether the test wafer meets a design specification, and to make the test wafer being reworked if the test wafer fails to meet the design specification.

15. The system for processing the test wafer in the photolithography process according to claim 14, wherein the historical compensation behaviours comprise m first type compensation behaviours corresponding to previous m processes on the i^{th} level by the equipment, and m is a positive integer.

16. The system for processing the test wafer in the photolithography process according to claim 15, wherein the compensation value generating module generates a weighted value corresponding to each of the first type compensation behaviours based on a measurement target and m measurement results generated in the previous m processes on the i^{th} level by the equipment and calculates the compensation value according to the weighted values and the first type compensation behaviours.

17. The system for processing the test wafer in the photolithography process according to claim 16, wherein the compensation value generating module respectively calculates a difference between each of the measurement results and the measurement target and generates the weighted values based on an order of the differences and a predetermined sum of the weighted values.

18. The system for processing the test wafer in the photolithography process according to claim 14, wherein the compensation value generating module calculates the compensation value based on a sum of the offsets between the i^{th} level and the other levels, the other levels being all the levels above the i^{th} level in the test wafer.

19. The system for processing the test wafer in the photolithography process according to claim 14, wherein the compensation value generating module obtains the offset corresponding to the process on the test wafer by at least one non-photolithography chamber and calculates the compensation value based on a weighted sum of the offsets.

20. The system for processing the test wafer in the photolithography process according to claim 14, wherein the historical compensation behaviours comprise a plurality of second type compensation behaviours corresponding to processes on a j^{th} level by the equipment, the j^{th} level is different from the i^{th} level and is the level most recently processed by the equipment, and j is a positive integer.

21. The system for processing the test wafer in the photolithography process according to claim 20, wherein the compensation value generating module calculates the compensation value based on a first type compensation behaviour corresponding to the process on the i^{th} level by the equipment at a certain time, the second type compensation behaviour corresponding to the process on the j^{th} level by the equipment at the certain time, and the second type compensation behaviour corresponding to the most recent process on the j^{th} level by the equipment.

22. The system for processing the test wafer in the photolithography process according to claim 14, wherein the control module obtains a measurement result generated from an exposure process performed on the test wafer based on the compensation value, and controls the equipment to process a lot corresponding to the test wafer according to the compensation value and the measurement result.

23. The system for processing the test wafer in the photolithography process according to claim 14, wherein the control module obtains a measurement result generated from an exposure process performed on the test wafer based on the compensation value and determines that the test wafer meets the design specification if the measurement result falls within a specified range.

24. The system for processing the test wafer in the photolithography process according to claim 23, wherein the measurement result comprises an overlay error obtained from an overlay measurement equipment.

25. The system for processing the test wafer in the photolithography process according to claim 23, wherein the measurement result comprises a critical dimension error obtained from a critical dimension measurement equipment.

26. The system for processing the test wafer in the photolithography process according to claim 14, wherein the compensation value generating module further calculates the compensation value according to a time of a previous process on a lot by the equipment, an equipment experience value of the equipment, results of processes on levels similar to the i^{th} level, and results of processes by an equipment similar to the equipment.
